(19) United States
(12) Patent Application Publication
(10) Pub. No.: US 2023/0395527 A1
(43) Pub. Date: Dec. 7, 2023

(54) SEMICONDUCTOR STRUCTURE AND MANUFACTURING METHOD THEREOF

(71) Applicant: Powerchip Semiconductor Manufacturing Corporation, Hsinchu (TW)

(72) Inventors: Shih-Ping Lee, Hsinchu City (TW); Bo-An Tsai, Hsinchu City (TW); Pin-Chieh Huang, Hsinchu County (TW)

(73) Assignee: Powerchip Semiconductor Manufacturing Corporation, Hsinchu (TW)

(21) Appl. No.: 17/858,988

(22) Filed: Jul. 6, 2022

(30) Foreign Application Priority Data
Jun. 6, 2022 (TW) 111120923

(51) Int. Cl. H01L 23/00; H01L 21/768; H01L 23/48; H01L 49/02

(52) U.S. Cl. CPC H01L 23/562; H01L 28/91; H01L 23/481; H01L 21/76898

(57) ABSTRACT

A semiconductor structure including a substrate, a through-substrate via (TSV), a first insulating layer, an isolation structure, and a capacitor is provided. The substrate includes a TSV region and a keep-out zone (KOZ) adjacent to each other. The TSV is located in the substrate in the TSV region. The first insulating layer is located between the TSV and the substrate. The isolation structure is located in the substrate in the KOZ. There are trenches in the isolation structure. A capacitor is located on the isolation structure and in the trenches.

### CROSS-REFERENCE TO RELATED APPLICATION

This application claims the priority benefit of Taiwan application serial no. 111120923, filed on Jun. 6, 2022. The entirety of the above-mentioned patent application is hereby incorporated by reference herein and made a part of this specification.

### BACKGROUND

### Technical Field

The invention relates to semiconductor structure and a manufacturing method thereof, and particularly relates to a semiconductor structure including a through-substrate via (TSV) and a manufacturing method thereof.

### Description of Related Art

Since the coefficient of thermal expansion (CTE) of the material of the TSV does not match the CTE of the material of the substrate, after the high temperature semiconductor process is performed, the stress caused by the TSV is generated. In addition, when the above-mentioned stress is applied to the substrate near the TSV, the electrical performance of the active device (e.g., transistor device) is degraded. Therefore, the current practice is to set a keep-out zone (KOZ) near the TSV, and the active device is not disposed in the KOZ, thereby preventing the active device from being affected by the stress. However, since the KOZ occupies the chip area, how to reduce the KOZ is the goal of continuous efforts at present.

### SUMMARY

The invention provides a semiconductor structure and a manufacturing method thereof, which can effectively reduce the KOZ.

The invention provides a semiconductor structure, which includes a substrate, a TSV, a first insulating layer, an isolation structure, and a capacitor. The substrate includes a TSV region and a KOZ adjacent to each other. The TSV is located in the substrate in the TSV region. The first insulating layer is located between the TSV and the substrate. The isolation structure is located in the substrate in the KOZ. There are trenches in the isolation structure. The capacitor is located on the isolation structure and in the trenches.

According to an embodiment of the invention, in the semiconductor structure, the KOZ may surround the TSV region.

According to an embodiment of the invention, in the semiconductor structure, the CTE of the isolation structure may be smaller than the CTE of the TSV.

According to an embodiment of the invention, in the semiconductor structure, the capacitor may include a first electrode, a second electrode, and a second insulating layer. The first electrode is located in the trenches. The second electrode is located in the trenches and is located on the first electrode. The second insulating layer is located between the first electrode and the second electrode.

According to an embodiment of the invention, in the semiconductor structure, the first electrode may be further located outside the trenches and may extend over the top surface of the substrate. A portion of the second electrode may be located outside of the trenches.

According to an embodiment of the invention, in the semiconductor structure, the isolation structure may include at least one isolation pillar. The isolation pillar may be located between two adjacent trenches. The capacitor may include at least one first electrode, at least one second electrode, and the isolation pillar. The first electrode and the second electrode are alternately arranged and are located in different trenches. The isolation pillar is located between the first electrode and the second electrode.

According to an embodiment of the invention, in the semiconductor structure, the capacitor may include a plurality of the first electrodes. The first electrodes may be electrically connected to each other.

According to an embodiment of the invention, in the semiconductor structure, the capacitor may include a plurality of the second electrodes. The second electrodes may be electrically connected to each other.

According to an embodiment of the invention, the semiconductor structure may further include a dielectric layer. The dielectric layer is located on the substrate. The TSV may be further located in the dielectric layer.

According to an embodiment of the invention, the semiconductor structure may further include a stop layer. The stop layer is located on the dielectric layer.

The invention provides a manufacturing method of a semiconductor structure, which includes the following steps. A substrate is provided. The substrate includes a TSV region and a KOZ adjacent to each other. A TSV is formed in the substrate in the TSV region. A first insulating layer is formed between the TSV and the substrate. An isolation structure is formed in the substrate in the KOZ. First trenches are formed in the isolation structure. A capacitor is formed on the isolation structure and in the first trenches.

According to an embodiment of the invention, in the manufacturing method of the semiconductor structure, the KOZ may surround the TSV region.

According to an embodiment of the invention, in the manufacturing method of the semiconductor structure, the method of forming the isolation structure may include the following steps. A patterned photoresist layer is formed on the substrate. A portion of the substrate is removed by using the patterned photoresist layer as a mask to form a second trench in the substrate. The patterned photoresist layer is removed. An isolation material layer filling in the second trench is formed on the substrate. The isolation material layer located outside the second trench is removed to form the isolation structure.

According to an embodiment of the invention, in the manufacturing method of the semiconductor structure, the method of the removing the isolation material layer located outside the second trench is, for example, a chemical mechanical polishing (CMP) method.

According to an embodiment of the invention, in the manufacturing method of the semiconductor structure, the isolation structure may include at least one isolation pillar. The isolation pillar may be located between two adjacent first trenches. The method of forming the first trench and the isolation pillar may include the following steps. A patterned photoresist layer is formed on the isolation structure. A portion of the isolation structure is removed by using the patterned photoresist layer as a mask to form the first trench and the isolation pillar.

According to an embodiment of the invention, the manufacturing method of the semiconductor structure may further include the following steps. Before forming the capacitor, the width of the first trench is enlarged and the width of the isolation pillar is reduced.

According to an embodiment of the invention, in the manufacturing method of the semiconductor structure, the method of enlarging the width of the first trench and reducing the width of the isolation pillar may include the following steps. A portion of the isolation structure exposed by the first trench is removed.

According to an embodiment of the invention, in the manufacturing method of the semiconductor structure, the method of removing the portion of the isolation structure exposed by the first trench is, for example, a dry etching method or a wet etching method.

According to an embodiment of the invention, in the manufacturing method of the semiconductor structure, the capacitor may include a first electrode, a second electrode, and a second insulating layer. The first electrode is located in the first trenches. The second electrode is located in the first trenches and is located on the first electrode. The second insulating layer is located between the first electrode and the second electrode.

According to an embodiment of the invention, in the manufacturing method of the semiconductor structure, the isolation structure may include at least one isolation pillar. The isolation pillar may be located between two adjacent first trenches. The capacitor may include at least one first electrode, at least one second electrode, and the isolation pillar. The first electrode and the second electrode are alternately arranged and are located in different first trenches. The isolation pillar is located between the first electrode and the second electrode.

Based on the above description, in the semiconductor structure and the manufacturing method thereof according to the invention, the TSV region and the KOZ are adjacent to each other, the TSV is located in the substrate in the TSV region, and the isolation structure is located in the substrate in the KOZ. In this way, the stress induced by the TSV can be blocked by the isolation structure, so the stress applied on the substrate can be reduced, thereby effectively reducing the KOZ. In addition, the capacitor is located on the isolation structure and in the trenches. That is, the capacitor can be located in the KOZ. Since the KOZ can be used as a capacitor region, the chip area can be efficiently utilized.

In order to make the aforementioned and other objects, features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1G are cross-sectional views illustrating a manufacturing process of a semiconductor structure according to some embodiments of the invention.

FIG. 2 is a top view of FIG. 1D.

FIG. 3A to FIG. 3C are cross-sectional views illustrating a manufacturing process of a semiconductor structure according to other embodiments of the invention.

FIG. 4A to FIG. 4B are cross-sectional views illustrating a manufacturing process of a semiconductor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

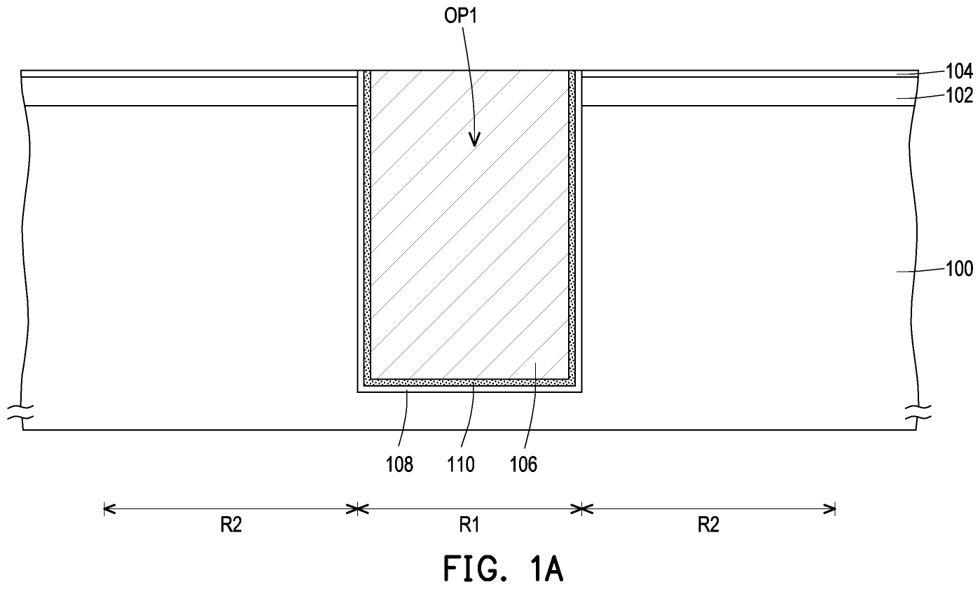

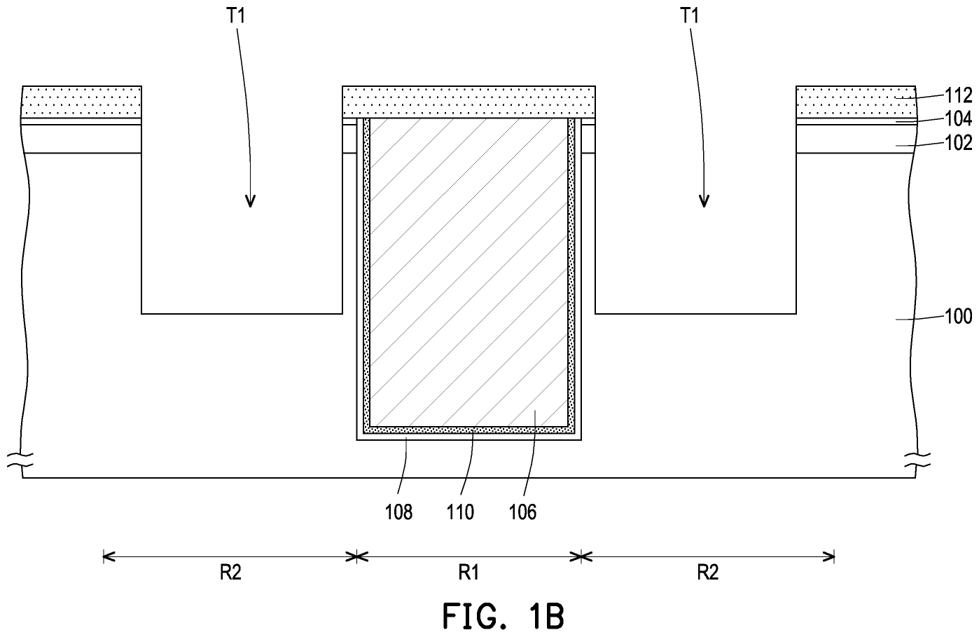

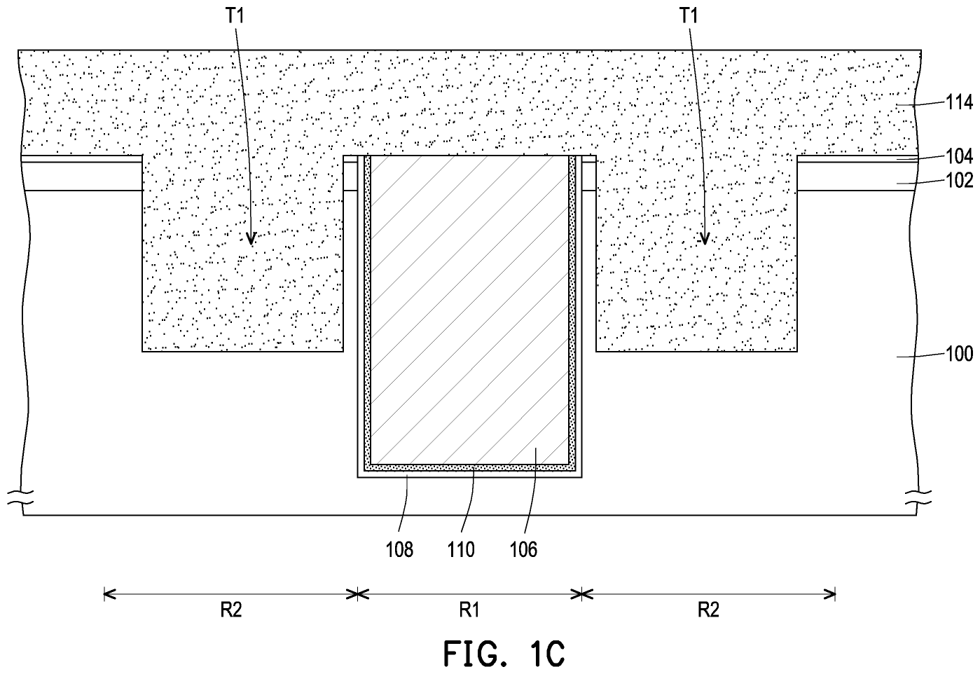

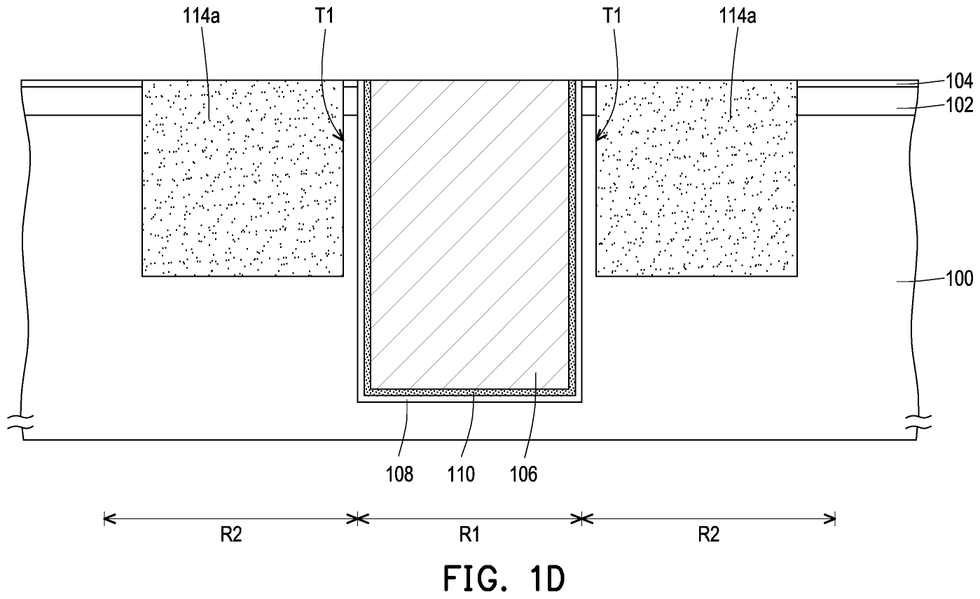

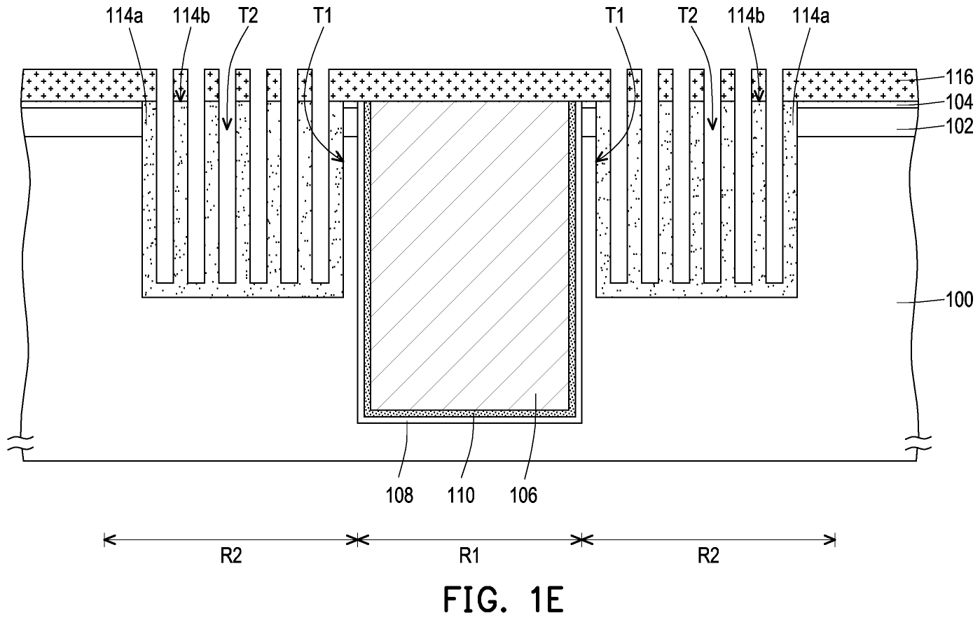

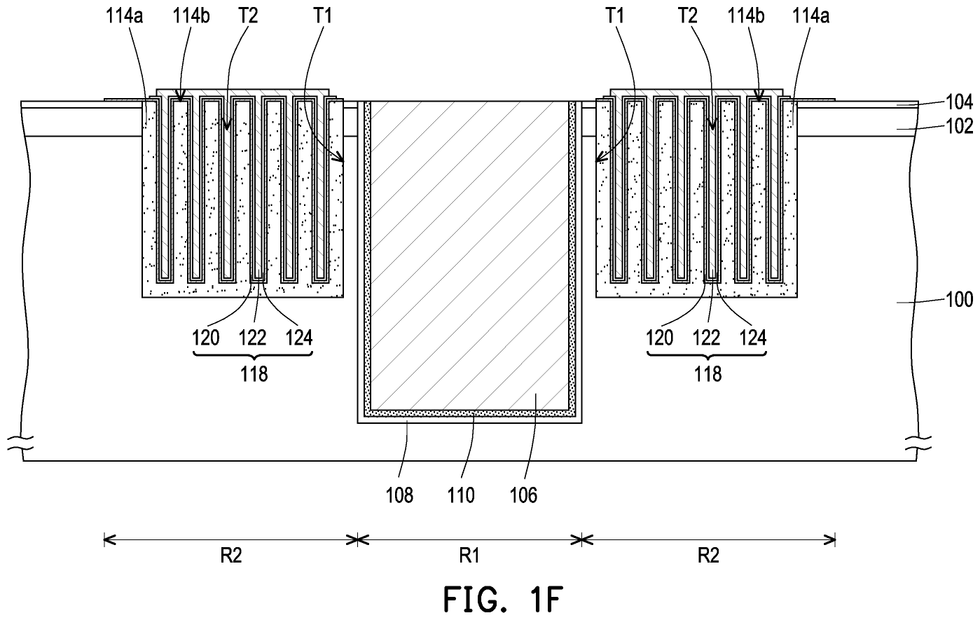

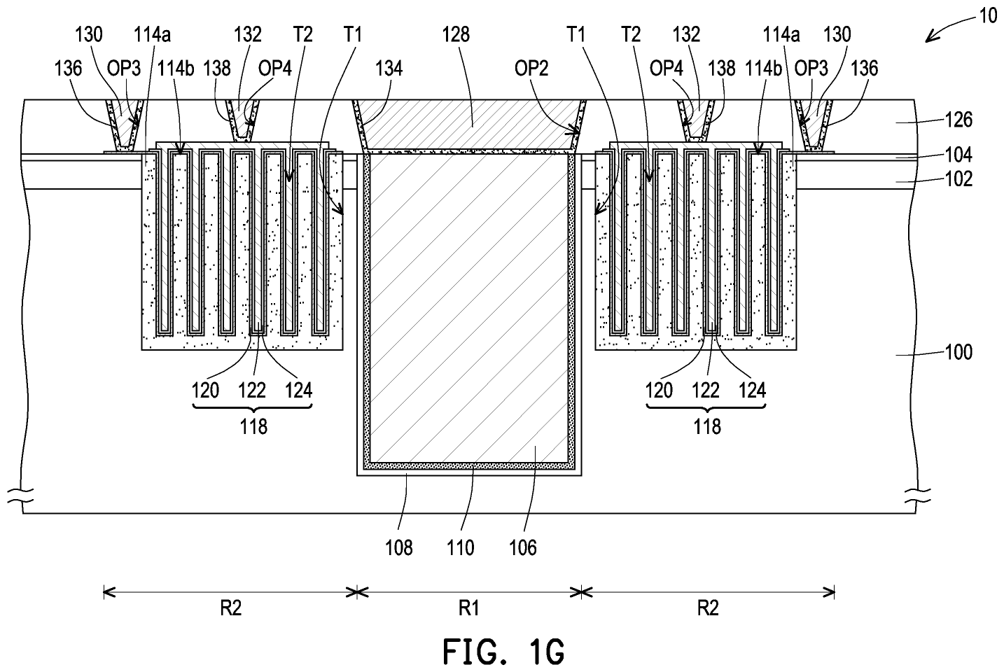

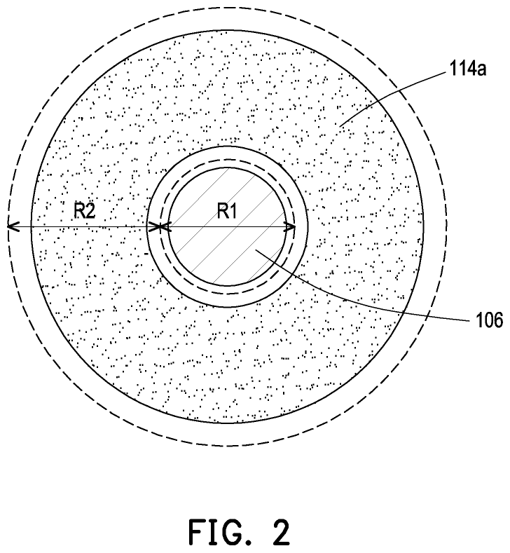

FIG. 1A to FIG. 1G are cross-sectional views illustrating a manufacturing process of a semiconductor structure according to some embodiments of the invention. FIG. 2 is a top view of FIG. 1D. In addition, in the top view of FIG. 2, some components in FIG. 1D are omitted to clearly illustrate the configuration relationship between the components in FIG. 2.

Referring to FIG. 1A, a substrate 100 is provided. The substrate 100 includes a TSV region R1 and a KOZ R2 adjacent to each other. The substrate 100 may be a semiconductor substrate such as a silicon substrate. In some embodiments, as shown in FIG. 2, the KOZ R2 may surround the TSV region R1.

A dielectric layer 102 may be formed on the substrate 100. The material of the dielectric layer 102 is, for example, silicon oxide. The method of forming the dielectric layer 102 is, for example, a chemical vapor deposition (CVD) method. In addition, although not shown in the figure, the required semiconductor device (e.g., the active device such as the transistor device) may be formed in the substrate 100, on the substrate 100 and/or in the dielectric layer 102, and the description thereof is omitted here.

A stop layer 104 may be formed on the dielectric layer 102. The material of the stop layer 104 is, for example, silicon nitride. The method of forming the stop layer 104 is, for example, a CVD method.

A TSV 106 is formed in substrate 100 in TSV region R1. In some embodiments, the TSV 106 may be a via-middle TSV. The via-middle TSV refers to the TSV formed after the transistor is formed and before the back end of line (BEOL) process. The material of the TSV 106 is, for example, copper.

In addition, an insulating layer 108 is formed between the TSV 106 and the substrate 100. The material of the insulating layer 108 is, for example, silicon oxide. In some embodiments, a barrier layer 110 may be formed between the TSV 106 and the insulating layer 108. The material of the barrier layer 110 is, for example, titanium, titanium nitride, tantalum, tantalum nitride, or a combination thereof.

In some embodiments, the method of forming the TSV 106, the barrier layer 110, and the insulating layer 108 may include the following steps. First, the substrate 100 may be patterned to form an opening OP1 in the substrate 100. Next, an insulating material layer (not shown), a barrier material layer (not shown), and a TSV material layer (not shown) may be sequentially formed in the opening OP1. Then, the TSV material layer, the barrier material layer, and the insulating material layer located outside the opening OP1 may be removed to form the TSV 106, the barrier layer 110, and the insulating layer 108. The method of removing the TSV material layer, the barrier material layer, and the insulating material layer located outside the opening OP1 is, for example, a CMP method.

Referring to FIG. 1B, a patterned photoresist layer 112 may be formed on the substrate 100. In the present embodiment, the patterned photoresist layer 112 may be formed on the stop layer 104, the TSV 106, the insulating layer 108, and the barrier layer 110. The patterned photoresist layer 112 may be formed by a lithography process.

A portion of the substrate 100 may be removed by using the patterned photoresist layer 112 as a mask to form a trench T1 in the substrate 100. In addition, in the process of forming the trench T1, a portion of the stop layer 104 and a portion of the dielectric layer 102 may be removed. The method of removing the portion of the stop layer 104, the portion of the dielectric layer 102, and the portion of the substrate 100 is, for example, a dry etching method.

Referring to FIG. 1C, the patterned photoresist layer 112 may be removed. The method of removing the patterned photoresist layer 112 is, for example, a dry stripping method or a wet stripping method.

An isolation material layer 114 filling the trench T1 may be formed on the substrate 100. The material of the isolation material layer 114 is, for example, silicon oxide or a high dielectric constant (high-k) material. The method of forming the isolation material layer 114 is, for example, a spin coating method, a CVD method, or a physical vapor deposition (PVD) method.

Referring to FIG. 1D, the isolation material layer 114 located outside the trench T1 may be removed to form an isolation structure 114a. Therefore, the isolation structure 114a may be formed in the substrate 100 in the KOZ R2. In some embodiments, as shown in FIG. 2, the isolation structure 114a may surround the TSV 106. The CTE of the isolation structure 114a may be smaller than the CTE of the TSV 106. In some embodiments, the isolation structure 114a may be a deep trench isolation (DTI) structure. The method of removing the isolation material layer 114 located outside the trench T1 is, for example, a CMP method.

Referring to FIG. 1E, a patterned photoresist layer 116 may be formed on the isolation structure 114a. In addition, the patterned photoresist layer 116 may be further formed on the stop layer 104, the TSV 106, the insulating layer 108, and the barrier layer 110. The patterned photoresist layer 116 may be formed by a lithography process.

A portion of the isolation structure 114a may be removed by using the patterned photoresist layer 116 as a mask to form trenches T2 and an isolation pillar 114b. Therefore, the trenches T2 may be formed in the isolation structure 114a, and the isolation structure 114a may include at least one isolation pillar 114b. The isolation pillar 114b may be located between two adjacent trenches T2. In some embodiments, the top-view pattern of the trench T2 may be a hole shape, a strip shape, or a ring shape. A method of removing the portion of the isolation structure 114a is, for example, a dry etching method.

Referring to FIG. 1F, the patterned photoresist layer 116 may be removed. The method of removing the patterned photoresist layer 116 is, for example, a dry stripping method or a wet stripping method.

A capacitor 118 is formed on the isolation structure 114a and in the trenches T2. In some embodiments, the capacitor 118 may be a metal-insulator-metal (MIM) capacitor.

The capacitor 118 may include an electrode 120, an electrode 122, and an insulating layer 124. In some embodiments, the electrode 120 may be electrically connected to a high voltage, and the electrode 122 may be grounded or electrically connected to a low voltage. The electrode 120 is located in the trenches T2. The electrode 120 may be further located outside the trenches T2 and may extend over the top surface of the substrate 100. The material of the electrode 120 is, for example, titanium, titanium nitride, or a combination thereof. The electrode 122 is located in the trenches T2 and is located on the electrode 120. A portion of the electrode 122 may be located outside of the trenches T2. The electrode 122 may be a single-layer structure or a multilayer structure. The material of the electrode 122 is, for example, titanium, titanium nitride, doped silicon germanium (SiGe), tungsten, or a combination thereof. The insulating layer 124 is located between the electrode 120 and the electrode 122. The material of the insulating layer 124 is, for example, a high-k material, silicon oxide, silicon oxynitride (SiON), silicon nitride, or a combination thereof.

In some embodiments, the method of forming the electrode 122, the insulating layer 124, and the electrode 120 may include the following steps. First, a first electrode material layer (not shown), an insulating material layer (not shown), and a second electrode material layer (not shown) filling into the trenches T2 may be sequentially formed. Then, the second electrode material layer, the insulating material layer, and the first electrode material layer may be respectively patterned to form the electrode 122, the insulating layer 124, and the electrode 120.

Referring to FIG. 1G, a dielectric layer 126 may be formed on the stop layer 104, the TSV 106, the insulating layer 108, the barrier layer 110, and the capacitor 118. The material of the dielectric layer 126 is, for example, silicon oxide. The method of forming the dielectric layer 126 is, for example, a CVD method.

A conductive layer 128, a conductive layer 130, and a conductive layer 132 may be formed in dielectric layer 126. The conductive layer 128, the conductive layer 130, and the conductive layer 132 may be electrically connected to the TSV 106, the electrode 120, and the electrode 122, respectively. The materials of the conductive layer 128, the conductive layer 130, and the conductive layer 132 are, for example, copper. In addition, a barrier layer 134 may be formed between the conductive layer 128 and the dielectric layer 126 and between the conductive layer 128 and the TSV 106, a barrier layer 136 may be formed between the conductive layer 130 and the dielectric layer 126 and between the conductive layer 130 and the electrode 120, and a barrier layer 138 may be formed between the conductive layer 132 and the dielectric layer 126 and between the conductive layer 132 and the electrode 122. The materials of the barrier layer 134, the barrier layer 136, and the barrier layer 138 are, for example, titanium, titanium nitride, tantalum, tantalum nitride, or a combination thereof.

In some embodiments, the method of forming the conductive layer 128, the conductive layer 130, the conductive layer 132, the barrier layer 134, the barrier layer 136, and the barrier layer 138 may include the following steps. First, an opening OP2, an opening OP3, and an opening OP4 may be formed in the dielectric layer 126. The opening OP2, the opening OP3, and the opening OP4 may expose the TSV 106, the electrode 120, and the electrode 122, respectively. Next, a barrier material layer (not shown) and a conductive material layer (not shown) may be sequentially formed in the opening OP2, the opening OP3, and the opening OP4. Then, the conductive material layer and the barrier material layer located outside the opening OP2, the opening OP3, and the opening OP4 may be removed to form the conductive layer 128, the conductive layer 130, the conductive layer 132, the barrier layer 134, the barrier layer 136, and the barrier layer 138. The method of removing the conductive material layer and the barrier material layer located outside the opening OP2, the opening OP3, and the opening OP4 is, for example, a CMP method.

Hereinafter, the semiconductor structure 10 of the present embodiment is described with reference to FIG. 1G. In addition, although the method for forming the semiconductor structure 10 is described by taking the above method as an example, the invention is not limited thereto.

Referring to FIG. 1G, a semiconductor structure 10 includes a substrate 100, a TSV 106, an insulating layer 108, an isolation structure 114a, and a capacitor 118. The substrate 100 includes a TSV region R1 and a KOZ R2 adjacent to each other. The TSV 106 is located in substrate 100 in TSV region R1. The insulating layer 108 is located between the TSV 106 and the substrate 100. The isolation structure 114a is located in the substrate 100 in the KOZ R2.

There are trenches T2 in the isolation structure 114a. The capacitor 118 is located on the isolation structure 114a and in the trenches T2. In addition, the semiconductor structure 10 may further include at least one of a dielectric layer 102 and a stop layer 104. The dielectric layer 102 is located on the substrate 100. The TSV 106 may be further located in the dielectric layer 102. The stop layer 104 is located on the dielectric layer 102. In some embodiments, the TSV 106 may be further located in the stop layer 104.

Furthermore, the remaining components in the semiconductor structure 10 may refer to the description of the above embodiments. Moreover, the material, the arrangement, the forming method, and the effect of each component in the semiconductor structure 10 have been described in detail in the above embodiments, and the description thereof is not repeated here.

Based on the above embodiments, in the semiconductor structure 10 and the manufacturing method thereof, the TSV region R1 and the KOZ R2 are adjacent to each other, the TSV 106 is located in the substrate 100 in the TSV region R1, and the isolation structure 114a is located in the substrate 100 in the KOZ R2. In this way, the stress induced by the TSV 106 can be blocked by the isolation structure 114a, so the stress applied on the substrate 100 can be reduced, thereby effectively reducing the KOZ R2. In addition, the capacitor 118 is located on the isolation structure 114a and in the trenches T2. That is, the capacitor 118 can be located in the KOZ R2. Since the KOZ R2 can be used as a capacitor region, the chip area can be efficiently utilized.

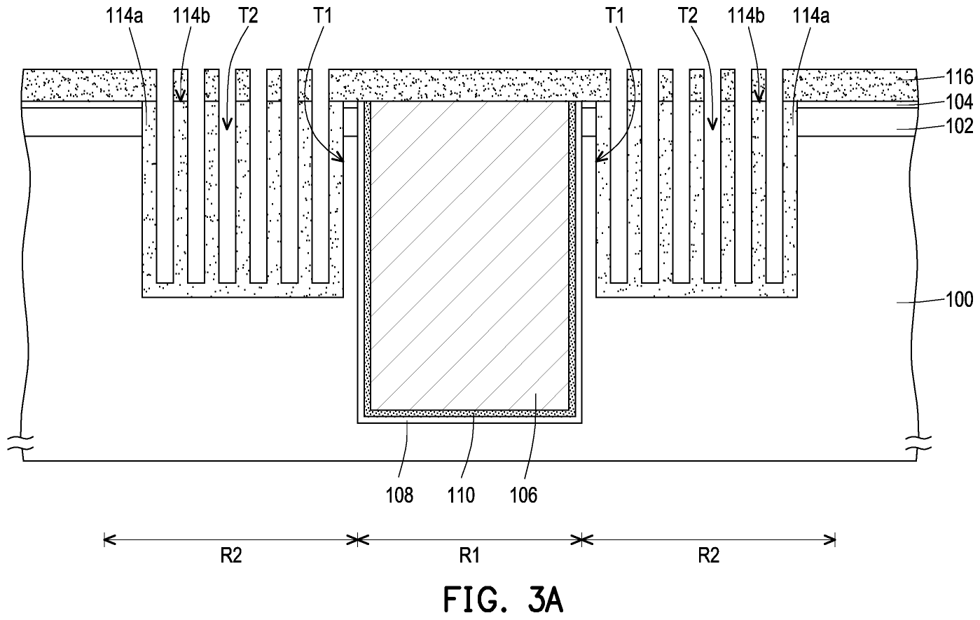

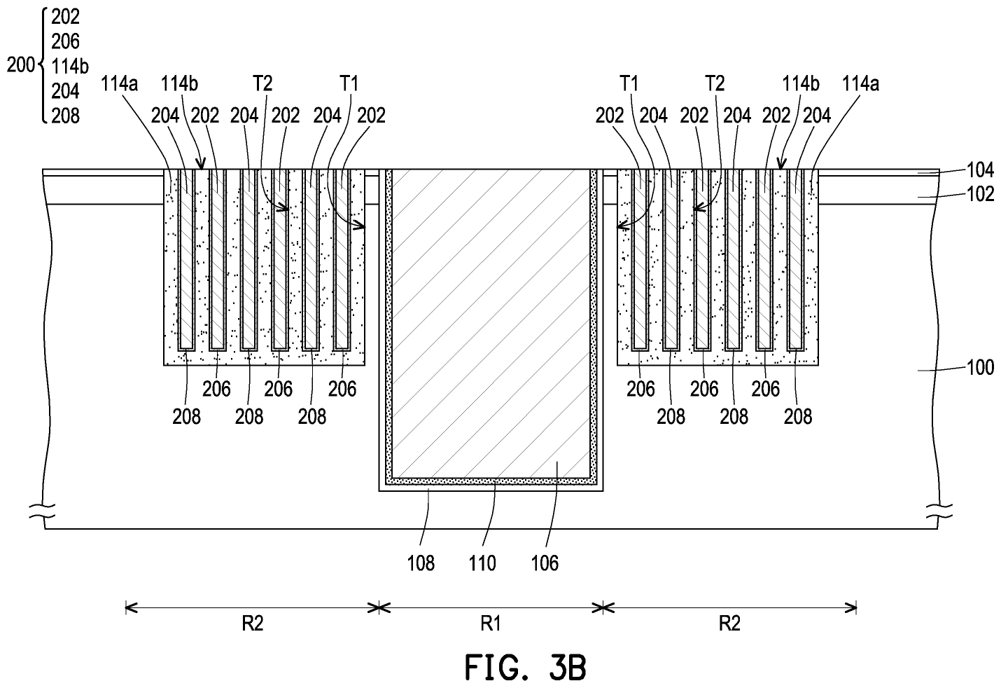

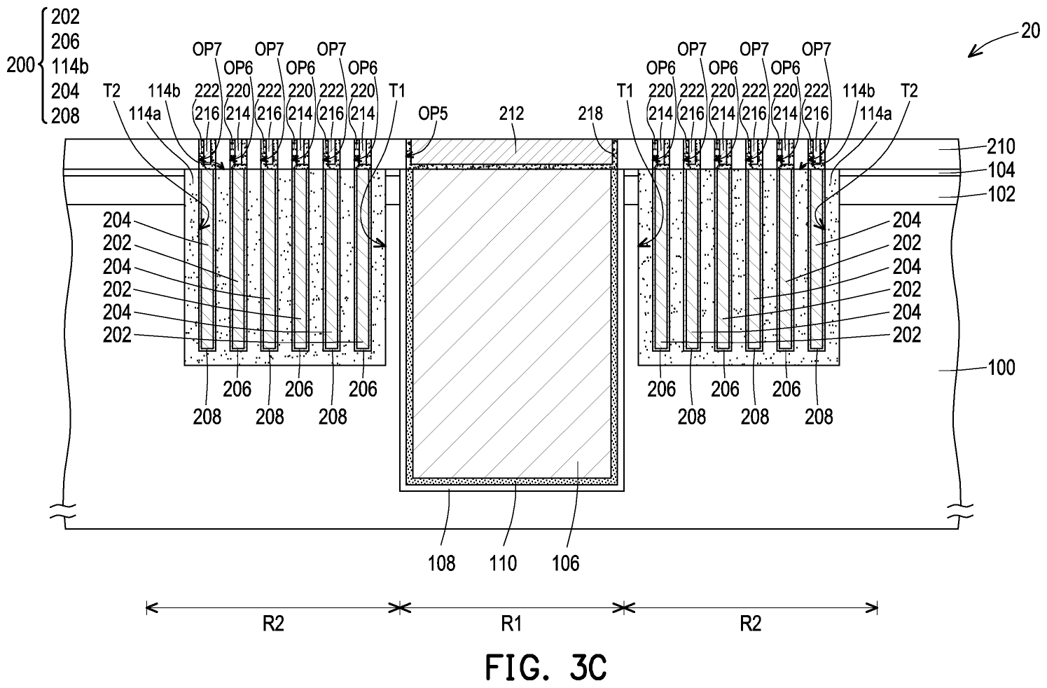

FIG. 3A to FIG. 3C are cross-sectional views illustrating a manufacturing process of a semiconductor structure according to other embodiments of the invention.

Referring to FIG. 3A, the structure as shown in FIG. 1E is provided. In addition, the structure of FIG. 1E and the manufacturing method thereof have been described in detail in the above embodiments, and the description thereof is not repeated here. In some embodiments, the material of the isolation structure 114a is, for example, silicon oxide or a high-k material. In some embodiments, the material of the isolation structure 114a may be a high-k material, thereby increasing the capacitance value of the subsequently formed capacitor 200 (FIG. 3B). The top-view pattern of the trench T2 may be a hole shape, a strip shape, or a ring shape. In some embodiments, the top-view pattern of the trench T2 may be a strip shape or a ring shape, thereby increasing the capacitance value of the subsequently formed capacitor 200 (FIG. 3B).

Referring to FIG. 3B, the patterned photoresist layer 116 may be removed. The method of removing the patterned photoresist layer 116 is, for example, a dry stripping method or a wet stripping method.

A capacitor 200 is formed on the isolation structure 114a and in the trenches T2. In some embodiments, the capacitor 200 may be a metal-oxide-metal (MOM) capacitor. In the text, the term “MOM capacitor” refers to a capacitor that has an insulator between two conductive layers. Although the insulator in the MOM capacitor may be oxide, the insulator may also be a dielectric material other than oxide. For example, the material of the isolation pillar 114b (insulator) in the capacitor 200 may be silicon oxide or a high-k material.

The capacitor 200 may include at least one electrode 202, at least one electrode 204, and the isolation pillar 114b. In the present embodiment, the capacitor 200 may include a plurality of the electrodes 202 and a plurality of the electrodes 204, but the invention is not limited thereto. As long as the number of the electrodes 202 is at least one, and the number of the electrodes 204 is at least one, it falls within the scope of the invention. In some embodiments, the electrodes 202 may be electrically connected to each other, and the electrodes 204 may be electrically connected to each other. For example, the electrodes 202 may be electrically connected to each other by an interconnect structure (not shown), and the electrodes 204 may be electrically connected to each other by an interconnect structure (not shown). In some embodiments, among the electrodes 202 and the electrodes 204, the electrode closest to the TSV 106 is the electrode 202, so the electrode 202 may be electrically connected to a high voltage, and the electrode 204 may be grounded or electrically connected to a low voltage. The electrode 202 and the electrode 204 are alternately arranged and are located in different trenches T2. The materials of the electrode 202 and the electrode 204 are, for example, tungsten, doped polysilicon or doped SiGe. The isolation pillar 114b is located between the electrode 202 and the electrode 204. The material of the isolation pillar 114b is, for example, silicon oxide or a high-k material. In some embodiments, the material of the isolation pillar 114b may be a high-k material, thereby increasing the capacitance value of the capacitor 200.

In some embodiments, the capacitor 200 may further include a barrier layer 206 and a barrier layer 208. For example, when the materials of the electrode 202 and the electrode 204 are metal such as tungsten, the capacitor 200 may further include the barrier layer 206 and the barrier layer 208. The barrier layer 206 is between the electrode 202 and the isolation structure 114a. The barrier layer 208 is between the electrode 204 and the isolation structure 114a. The materials of the barrier layer 206 and the barrier layer 208 are, for example, titanium, titanium nitride, tantalum, tantalum nitride, or a combination thereof.

In some embodiments, the method of forming the electrode 202, the electrode 204, the barrier layer 206, and the barrier layer 208 may include the following steps. First, a barrier material layer (not shown) and an electrode material layer (not shown) filling the trenches T2 may be sequentially formed. Then, the electrode material layer and the barrier material layer located outside the trenches T2 may be removed to form the electrode 202, the electrode 204, the barrier layer 206, and the barrier layer 208. The method of removing the electrode material layer and the barrier material layer located outside the trenches T2 is, for example, a CMP method.

Referring to FIG. 3C, a dielectric layer 210 may be formed on the stop layer 104, the TSV 106, the insulating layer 108, the barrier layer 110, the isolation structure 114a, and the capacitor 200. The material of the dielectric layer 210 is, for example, silicon oxide. The method of forming the dielectric layer 210 is, for example, a CVD method.

A conductive layer 212, a conductive layer 214, and a conductive layer 216 may be formed in dielectric layer 210. The conductive layer 212, the conductive layer 214, and the conductive layer 216 may be electrically connected to the TSV 106, the electrode 202, and the electrode 204, respectively. The materials of the conductive layer 212, the conductive layer 214, and the conductive layer 216 are, for example, copper. In addition, a barrier layer 218 may be formed between the conductive layer 212 and the dielectric layer 210 and between the conductive layer 212 and the TSV 106, a barrier layer 220 may formed between the conductive layer 214 and the dielectric layer 210 and between the conductive layer 214 and the electrode 202, and a barrier layer 222 may be formed between the conductive layer 216 and the dielectric layer 210 and between the conductive layer 216 and the electrode 204. The materials of the barrier layer 218, the barrier layer 220, and the barrier layer 222 are, for example, titanium, titanium nitride, tantalum, tantalum nitride, or a combination thereof.

In some embodiments, the method of forming the conductive layer 212, the conductive layer 214, the conductive layer 216, the barrier layer 218, the barrier layer 220, and the barrier layer 222 may include the following steps. First, an opening OP5, an opening OP6, and an opening OP7 may be formed in the dielectric layer 210. The opening OP5, the opening OP6, and the opening OP7 may expose TSV 106, the electrode 202, and the electrode 204, respectively. Next, a barrier material layer (not shown) and a conductive material layer (not shown) may be sequentially formed in the opening OP5, the opening OP6, and the opening OP7. Next, the conductive material layer and the barrier material layer located outside the opening OP5, the opening OP6, and the opening OP7 may be removed to form the conductive layer 212, the conductive layer 214, the conductive layer 216, the barrier layer 218, the barrier layer 220, and the barrier layer 222. The method of removing the conductive material layer and the barrier material layer located outside the opening OP5, the opening OP6, and the opening OP7 is, for example, a CMP method.

In some embodiments, another capacitor (e.g., MOM capacitor) (not shown) electrically connected to the capacitor 200 may be formed above the capacitor 200, and the description thereof is omitted here.

Hereinafter, the semiconductor structure 20 of the present embodiment is described with reference to FIG. 3C. In addition, although the method for forming the semiconductor structure 20 is described by taking the above method as an example, the invention is not limited thereto.

Referring to FIG. 3C, a semiconductor structure 20 includes a substrate 100, a TSV 106, an insulating layer 108, an isolation structure 114a, and a capacitor 200. The substrate 100 includes a TSV region R1 and a KOZ R2 adjacent to each other. The TSV 106 is located in substrate 100 in TSV region R1. The insulating layer 108 is located between the TSV 106 and the substrate 100. The isolation structure 114a is located in the substrate 100 in the KOZ R2. There are trenches T2 in the isolation structure 114a. The capacitor 200 is located on the isolation structure 114a and in the trenches T2. In addition, the semiconductor structure 20 may further include at least one of a dielectric layer 102 and a stop layer 104. The dielectric layer 102 is located on the substrate 100. The TSV 106 may be further located in the dielectric layer 102. The stop layer 104 is located on the dielectric layer 102. In some embodiments, the TSV 106 may be further located in the stop layer 104.

Furthermore, the remaining components in the semiconductor structure 20 may refer to the description of the above embodiments. Moreover, the material, the arrangement, the forming method, and the effect of each component in the semiconductor structure 20 have been described in detail in the above embodiments, and the description thereof is not repeated here.

Based on the above embodiments, in the semiconductor structure 20 and the manufacturing method thereof, the TSV region R1 and the KOZ R2 are adjacent to each other, the TSV 106 is located in the substrate 100 in the TSV region R1, and the isolation structure 114a is located in the substrate 100 in the KOZ R2. In this way, the stress induced by the TSV 106 can be blocked by the isolation structure 114a, so the stress applied on the substrate 100 can be reduced, thereby effectively reducing the KOZ R2. In addition, the capacitor 200 is located on the isolation structure 114a and in the trenches T2. That is, the capacitor 200 can be located in the KOZ R2. Since the KOZ R2 can be used as a capacitor region, the chip area can be efficiently utilized.

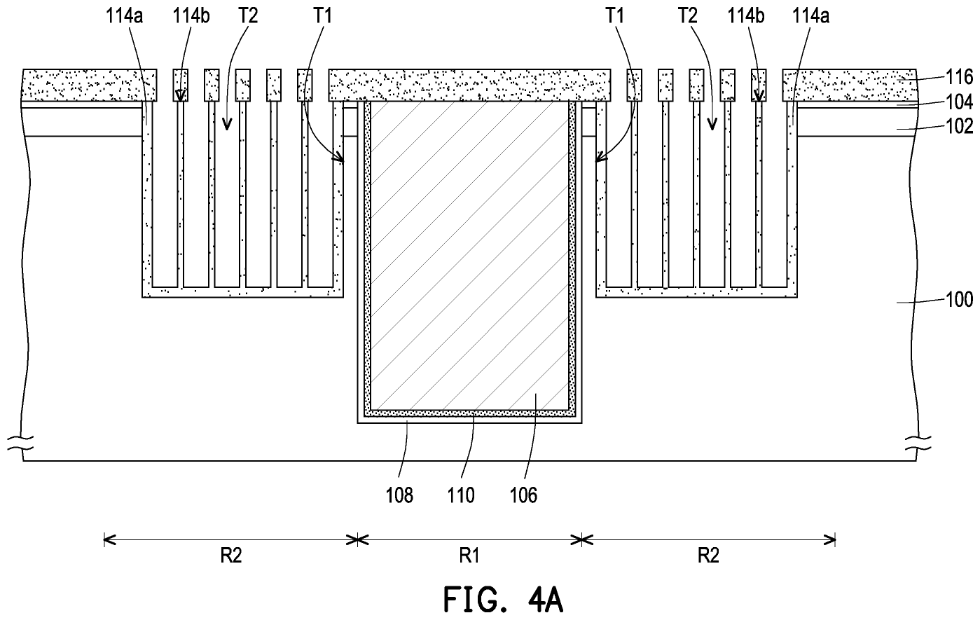

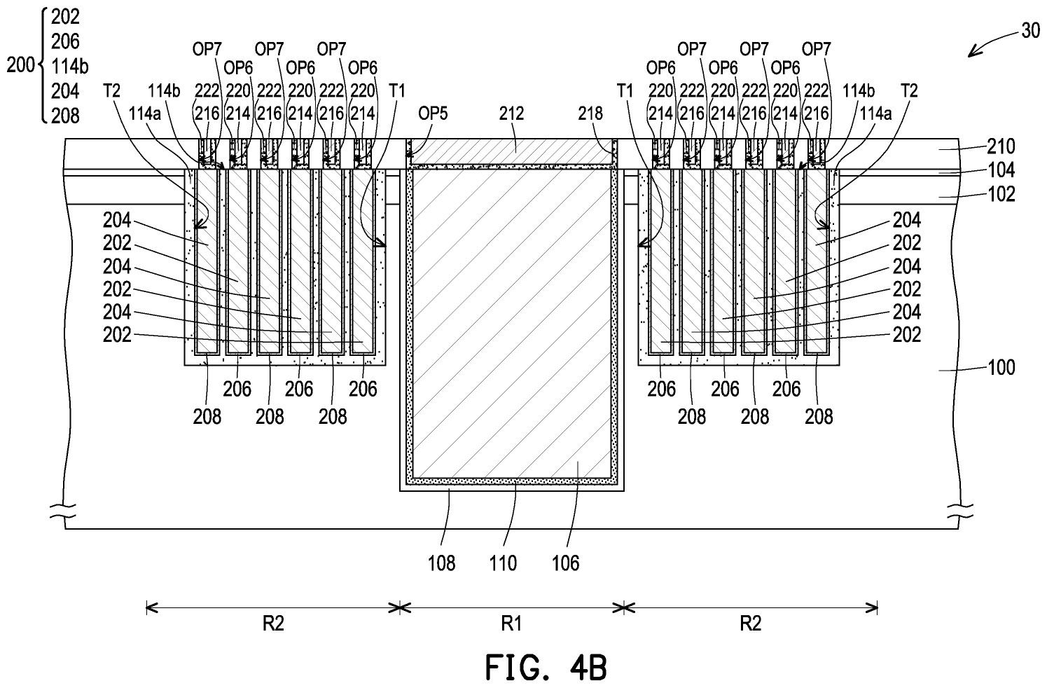

FIG. 4A to FIG. 4B are cross-sectional views illustrating a manufacturing process of a semiconductor structure according to other embodiments of the invention.

Referring to FIG. 4A, the structure as shown in 3A is provided. In addition, the structure of FIG. 3A and the manufacturing method thereof have been described in detail in the above embodiments, and the description thereof is not repeated here.

The width of the trench T2 may be enlarged and the width of the isolation pillar 114b may be reduced, thereby helping to increase the capacitance value of the subsequently formed capacitor 200 (FIG. 4B). The method of enlarging the width of the trench T2 and reducing the width of the isolation pillar 114b may include removing a portion of the isolation structure 114a exposed by the trench T2. In some embodiments, in the process of enlarging the width of the trench T2 and reducing the width of the isolation pillar 114b, the depth of the trench T2 may be increased simultaneously. The method of removing the portion of the isolation structure 114a exposed by the trench T2 is, for example, a dry etching method or a wet etching method.

Referring to FIG. 4B, after the width of the trench T2 is enlarged and the width of the isolation pillar 114b is reduced, the steps as shown in FIG. 3B and FIG. 3C may be performed to form a semiconductor structure 30, and the description thereof is not repeated here.

In some embodiments, another capacitor (e.g., MOM capacitor) (not shown) electrically connected to the capacitor 200 may be formed above the capacitor 200, and the description thereof is omitted here.

Hereinafter, the semiconductor structure 30 of the present embodiment is described with reference to FIG. 4B. In addition, although the method for forming the semiconductor structure 30 is described by taking the above method as an example, the invention is not limited thereto.

Referring to FIG. 4B, a semiconductor structure 30 includes a substrate 100, a TSV 106, an insulating layer 108, an isolation structure 114a, and a capacitor 200. The substrate 100 includes a TSV region R1 and a KOZ R2 adjacent to each other. The TSV 106 is located in substrate 100 in TSV region R1. The insulating layer 108 is located between the TSV 106 and the substrate 100. The isolation structure 114a is located in the substrate 100 in the KOZ R2. There are trenches T2 in the isolation structure 114a. The capacitor 200 is located on the isolation structure 114a and in the trenches T2. In addition, the semiconductor structure 30 may further include at least one of a dielectric layer 102 and a stop layer 104. The dielectric layer 102 is located on the substrate 100. The TSV 106 may be further located in the dielectric layer 102. The stop layer 104 is located on the dielectric layer 102. In some embodiments, the TSV 106 may be further located in the stop layer 104.

Furthermore, the remaining components in the semiconductor structure 30 may refer to the description of the above embodiments. Moreover, the material, the arrangement, the forming method, and the effect of each component in the semiconductor structure 30 have been described in detail in the above embodiments, and the description thereof is not repeated here.

Based on the above embodiments, in the semiconductor structure 30 and the manufacturing method thereof, the TSV region R1 and the KOZ R2 are adjacent to each other, the TSV 106 is located in the substrate 100 in the TSV region R1, and the isolation structure 114a is located in the substrate 100 in the KOZ R2. In this way, the stress induced by the TSV 106 can be blocked by the isolation structure 114a, so the stress applied on the substrate 100 can be reduced, thereby effectively reducing the KOZ R2. In addition, the capacitor 200 is located on the isolation structure 114a and in the trenches T2. That is, the capacitor 200 can be located in the KOZ R2. Since the KOZ R2 can be used as a capacitor region, the chip area can be efficiently utilized.

In summary, in the semiconductor structure and the manufacturing method thereof of the aforementioned embodiments, the stress induced by the TSV can be blocked by the isolation structure, so the stress applied on the substrate can be reduced, thereby effectively reducing the KOZ. In addition, since the KOZ can be used as a capacitor region, the chip area can be efficiently utilized.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate comprising a through-substrate via (TSV) region and a keep-out zone (KOZ) adjacent to each other;
a TSV located in the substrate in the TSV region;
a first insulating layer located between the TSV and the substrate;
an isolation structure located in the substrate in the KOZ, wherein there are trenches in the isolation structure; and
a capacitor located on the isolation structure and in the trenches.

2. The semiconductor structure according to claim 1, wherein the KOZ surrounds the TSV region.

3. The semiconductor structure according to claim 1, wherein a coefficient of thermal expansion (CTE) of the isolation structure is smaller than a CTE of the TSV.

4. The semiconductor structure according to claim 1, wherein the capacitor comprises:
a first electrode located in the trenches;
a second electrode located in the trenches and located on the first electrode; and
a second insulating layer located between the first electrode and the second electrode.

5. The semiconductor structure according to claim 4, wherein
the first electrode is further located outside the trenches and extends over a top surface of the substrate, and
a portion of the second electrode is located outside of the trenches.

6. The semiconductor structure according to claim 1, wherein the isolation structure comprises at least one isolation pillar, the isolation pillar is located between two adjacent trenches, and the capacitor comprises:
at least one first electrode and at least one second electrode, wherein the first electrode and the second electrode are alternately arranged and are located in different trenches; and
the isolation pillar located between the first electrode and the second electrode.

7. The semiconductor structure according to claim 6, wherein the capacitor comprises a plurality of the first electrodes, and the first electrodes are electrically connected to each other.

8. The semiconductor structure according to claim 6, wherein the capacitor comprises a plurality of the second electrodes, and the second electrodes are electrically connected to each other.

9. The semiconductor structure according to claim 1, further comprising:
a dielectric layer located on the substrate, wherein the TSV is further located in the dielectric layer.

10. The semiconductor structure according to claim 9, further comprising:
a stop layer located on the dielectric layer.

11. A manufacturing method of a semiconductor structure, comprising:
providing a substrate, wherein the substrate comprises a TSV region and a KOZ adjacent to each other;
forming a TSV in the substrate in the TSV region;
forming a first insulating layer between the TSV and the substrate;
forming an isolation structure in the substrate in the KOZ;
forming first trenches in the isolation structure; and
forming a capacitor on the isolation structure and in the first trenches.

12. The manufacturing method of the semiconductor structure according to claim 11, wherein the KOZ surrounds the TSV region.

13. The manufacturing method of the semiconductor structure according to claim 11, wherein a method of forming the isolation structure comprises:
forming a patterned photoresist layer on the substrate;
removing a portion of the substrate by using the patterned photoresist layer as a mask to form a second trench in the substrate;
removing the patterned photoresist layer;
forming an isolation material layer filling the second trench on the substrate; and
removing the isolation material layer located outside the second trench to form the isolation structure.

14. The manufacturing method of the semiconductor structure according to claim 13, wherein a method of removing the isolation material layer located outside the second trench comprises a chemical mechanical polishing method.

15. The manufacturing method of the semiconductor structure according to claim 11, the isolation structure comprises at least one isolation pillar, the isolation pillar is located between two adjacent first trenches, and a method of forming the first trench and the isolation pillar comprises:
forming a patterned photoresist layer on the isolation structure; and
removing a portion of the isolation structure by using the patterned photoresist layer as a mask to form the first trench and the isolation pillar.

16. The manufacturing method of the semiconductor structure according to claim 15, further comprising:
enlarging a width of the first trench and reducing a width of the isolation pillar before forming the capacitor.

17. The manufacturing method of the semiconductor structure according to claim 16, wherein a method of enlarging the width of the first trench and reducing the width of the isolation pillar comprises:
removing a portion of the isolation structure exposed by the first trench.

18. The manufacturing method of the semiconductor structure according to claim 17, wherein a method of removing the portion of the isolation structure exposed by the first trench comprises a dry etching method or a wet etching method.

19. The manufacturing method of the semiconductor structure according to claim 11, wherein the capacitor comprises:
a first electrode located in the first trenches;
a second electrode located in the first trenches and located on the first electrode; and
a second insulating layer located between the first electrode and the second electrode.

20. The manufacturing method of the semiconductor structure according to claim 11, wherein the isolation structure comprises at least one isolation pillar, the isolation pillar is located between two adjacent first trenches, and the capacitor comprises:
at least one first electrode and at least one second electrode, wherein the first electrode and the second electrode are alternately arranged and are located in different first trenches; and
the isolation pillar located between the first electrode and the second electrode.
